(19) United States
(12) Patent Application Publication
(10) Pub. No.: US 2008/0212620 A1
(43) Pub. Date: Sep. 4, 2008

(54) MICROSPHERE FIBER LASER SYSTEM

(75) Inventor: HOSSIN A. ABDELDAYEM, Laurel, MD (US)

Correspondence Address: NASA GODDARD SPACE FLIGHT CENTER, 8800 GREENBELT ROAD, MAIL CODE 140.1, GREENBELT, MD, 20771, US

(73) Assignee: NASA Headquarters, Washington, DC (US)

(21) Appl. No.: 11/782,421

(22) Filed: Jul. 24, 2007

Related U.S. Application Data
(60) Provisional application No. 60/820,633, filed on Jul. 28, 2006.

(51) Int. Cl. H01S 3/30; H01L 21/00

(52) U.S. Cl. 372/6; 438/31; 257/E21.001

(57) ABSTRACT

A microsphere fiber laser system includes a laser beam conducting fiber coated with doped microspheres. One end of the fiber is pumped with a pumping laser. The other end of the fiber is an output. Microspheres with different dopants may be used to obtain outputs of different wavelengths. The microspheres may be attached to an outer surface of a solid fiber or to the internal wall of a hollow fiber.

### CROSS-REFERENCE TO RELATED APPLICATIONS

This application claims the benefit of priority of U.S. provisional patent application Ser. No. 60/820,633 filed on Jul. 28, 2006, which is hereby incorporated by reference.

### ORIGIN OF INVENTION

The invention described herein was made by an employee of the United States Government, and may be manufactured and used by or for the Government for governmental purposes without the payment of any royalties thereon or therefor.

### BACKGROUND OF THE INVENTION

Laser technology is of great importance for space exploration. Space exploration applications of laser technology include surface-chemical analyses and detection of organic compounds and biomarker gases on other planets. Laser technology may also be used for remote measurements of atmospheric aerosols, clouds, ozone layer, water vapor, carbon, and methane, as well as profiling wind measurements, surface topography, mapping vegetation and measuring subsurface ocean layers. Civilian applications of laser technology include the motion picture industry, medical applications, printing, airports, national security agencies, computers and, in the future, optical computers.

A broad range of laser wavelengths may be used for many laser applications. Present laser systems are generally single wavelength systems. Therefore, if multiple laser wavelengths are needed, then multiple lasers must be provided. Providing multiple lasers is expensive. In addition, present laser systems are less reliable in harsh environments. The present invention can produce multiple laser lines and, therefore, replace several existing lasers. It may be used on the ground, in the air or in outer space. Compared to existing lasers, the present invention is more durable, lighter in weight, more rugged and cheaper. It is also capable of producing a wider range of laser powers.

### SUMMARY OF THE INVENTION

It is an object of an embodiment of the claimed invention to provide a microspherical fiber laser system that can generate multiple laser outputs.

One aspect of an embodiment of the claimed invention may include a microsphere fiber laser system comprising a laser beam conducting fiber having an input end and an output end; a plurality of doped microspheres adhesively attached to the fiber; and at least one pump laser for injecting a laser beam into the input end of the fiber; wherein the laser beam excites the doped microspheres to generate an output laser beam that is extracted at the output end of the fiber.

In some embodiments the microspheres are on an external surface of a solid fiber and in other embodiments the microspheres are on an internal surface of a hollow fiber. The doped microspheres may include microspheres having different dopants.

Another aspect of an embodiment of the claimed invention may include a method of making a microsphere laser apparatus comprising winding a laser beam conducting fiber around a rotatable cylinder; heating the fiber as the cylinder rotates; and attaching microspheres to the heated fiber as the cylinder rotates. The method may further comprise winding the fiber over the attached microspheres and repeating the heating and attaching steps.

A further aspect of an embodiment of the claimed invention may include a method of making a microsphere laser apparatus comprising providing a melt of a laser beam conducting fiber in a container having an opening at a bottom thereof, drawing the melt out of the container at the opening to solidify the fiber; and attaching microspheres to the fiber as it is pulled from the container.

Yet another aspect of an embodiment of the claimed invention may include a method of making a microsphere laser system comprising providing a melt of a laser beam conducting fiber in a container having an opening at a bottom thereof and having a central hollow mandrel; providing the hollow mandrel with microspheres; drawing the melt out of the container at the opening to form a hollow fiber; and inserting the microspheres into the hollow fiber.

Still another aspect of an embodiment of the claimed invention may include a method of making a microsphere laser system, comprising winding a hollow fiber around a cylinder; and injecting microspheres into one end of the hollow fiber. The microspheres may be mixed with a liquid prior to injecting.

A further aspect of an embodiment of the claimed invention may include a method of making a microsphere laser system comprising providing a fiber, a fiber supply cylinder and a fiber take-up cylinder; passing the fiber through a solvent to remove a coating on the fiber; passing the fiber through an adhesive; passing the fiber through a supply of microspheres; and winding the fiber around the take-up cylinder.

An additional aspect of an embodiment of the claimed invention may include an apparatus comprising a laser beam conducting fiber having an input end and an output end; and a plurality of doped microspheres disposed inside the fiber.

The embodiments of the invention will be better understood, and further objects, features, and advantages thereof will become more apparent from the following description of the preferred embodiments, taken in conjunction with the accompanying drawings.

### BRIEF DESCRIPTION OF THE DRAWINGS

In the drawings, which are not necessarily to scale, like or corresponding parts are denoted by like or corresponding reference numerals.

FIG. 1 is a view of a microsphere illustrating multiple internal reflection of a laser beam.

FIG. 2 illustrates the connection of a microsphere with a fiber.

FIG. 3 illustrates an apparatus for attaching microspheres to a fiber.

FIG. 4 is similar to FIG. 3 illustrating multiple layers of fiber.

FIG. 4A is an enlarged view of a portion of FIG. 4.

FIGS. 5 illustrates laser line outputs from 5 μm (micron) size microspheres.

FIG. 6 illustrates the apparatus in use.

FIG. 7 illustrates an alternate method of adhering microspheres to the outside surface of a fiber.

FIG. 8 illustrates an apparatus for fabricating a hollow fiber that is filled with microspheres.

FIG. 9 illustrates a solid fiber termination for the fiber of FIG. 8.

FIG. 10 illustrates an alternate method of applying microspheres to the inside surface of a hollow fiber.

FIG. 11 illustrates another method of adhering the microspheres to the fiber.

### DETAILED DESCRIPTION OF THE PREFERRED EMBODIMENTS

A technological revolution is occurring in the field of fiber lasers and fiber communications. Over the past several years, the level of power has increased from about 100 watts to nearly a kilowatt peak power. Concurrent with these advances has been research on the optical properties of small solid microspheres. A number of nonlinear optical effects including second and third harmonic generation, four wave mixing, two photon absorption, stimulated Raman scattering and lasing phenomena have been observed in both solid microspheres and liquid droplets.

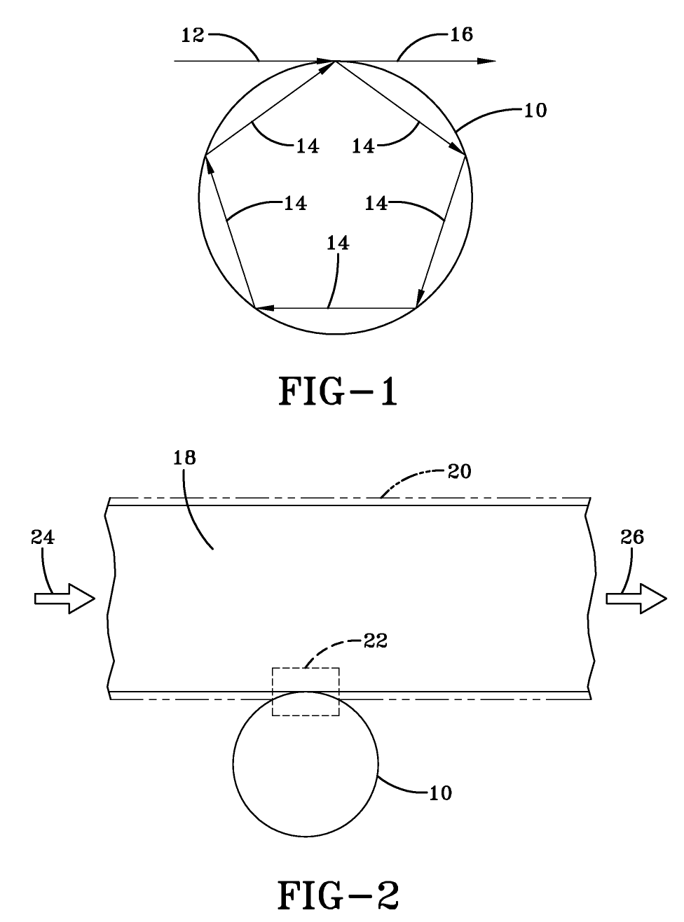

The present invention utilizes solid microspheres treated with certain dopants to generate one or more laser lines that can be used for research purposes. FIG. 1 illustrates a solid doped microsphere 10 on which is impinging a laser pumping beam 12 of a certain wavelength. The beam 12 enters the microsphere 10 and undergoes multiple internal reflections 14 until such time that sufficient energy has been built up that a laser beam 16 exits the microsphere 10, at a different wavelength than the pumping beam 12. In fact, due to the chemical nature of the dopants used, multiple wavelengths are actually produced.

The surface of the microsphere 10 acts as a thick lens to enhance the internal intensity of the input laser radiation while the spherical shape acts as an optical cavity that provides feedback at specific wavelengths.

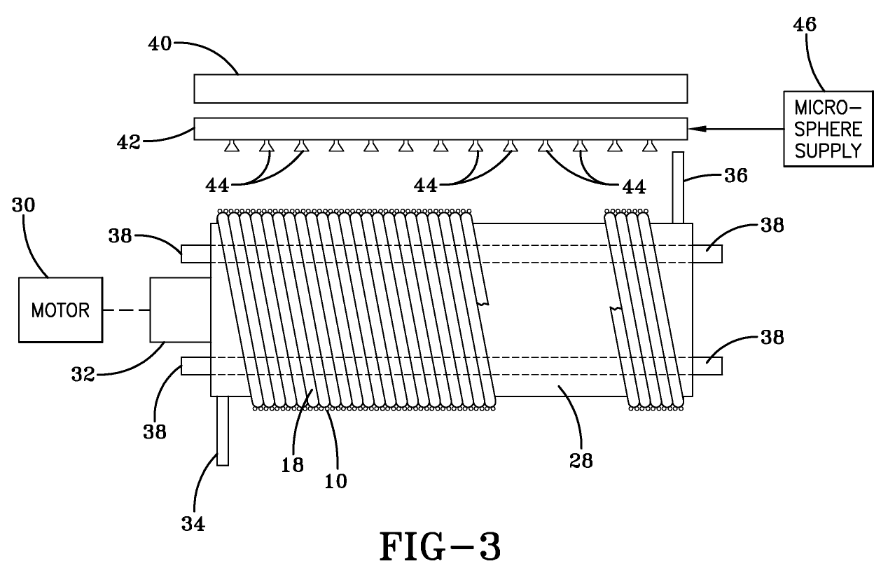

FIG. 2 illustrates the microsphere 10 attached to a fiber 18. Fiber 18 includes a coating 20 of wax to protect it during handling. The coating 20 of wax will evaporate during the process of attaching the microspheres to the fiber 18. Microsphere 10 is adhesively attached to fiber 18 at a coupling region 22 where a pumping laser beam 24 enters the microsphere 10, and where the output laser beam 26 exits. In a typical arrangement, the fiber 18 may be made of silica, PMMA (polymethylemethacrylate) or the like, and the microsphere 10 may also be of the same material. In this way, the coupling region 22 joins two materials with the same or closely similar index of refraction to facilitate index matching for the entry and exit of the laser beams. FIG. 2 shows a microsphere 10 of smaller dimension than the fiber 18. However, microspheres of the same or greater dimension than the fiber 18 are equally applicable.

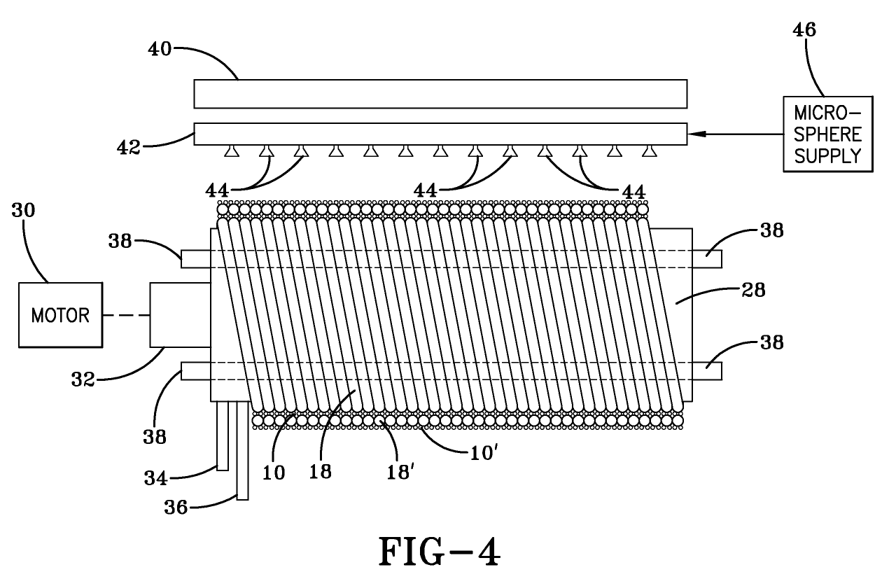

FIG. 3 illustrates one example of a process for applying microspheres to a fiber. The arrangement of FIG. 3 includes a cylinder 28 around which is wound a length of fiber 18. The cylinder 28 is rotated by a motor 30 connected to an axle 32. The motor 30 is computer programmed to rotate the cylinder 28 at a rate of speed such that the fiber 18 on the cylinder 28 is heated to below its melting temperature by a heater 40. The cylinder 28 continues to rotate as the fiber 18 is sprayed with microspheres using a fine powder sprayer 42. The rotation process is continued until the whole fiber 18 on cylinder 28 is coated with microspheres. One end 34 of fiber 18 constitutes a laser input and the other end 36 constitutes a laser output. The cylinder 28, which may be made of aluminum, includes cooling passageways 38 that are employed when the apparatus is used in the field.

The heater 40 heats the silica fiber 18 to around 1500° C. During the heating procedure the wax coating 20 (FIG. 2) on the fiber 18 melts away, at around 90° C. or less. The spray gun 42 includes a plurality of nozzles 44 and is supplied with microspheres from a microsphere supply 46. The microspheres become adhesively attached to the tacky fiber 18 and completely coat it. Although a single layer of fiber 18 is illustrated, in actuality many such layers would be used, depending upon the power requirements for a particular application.

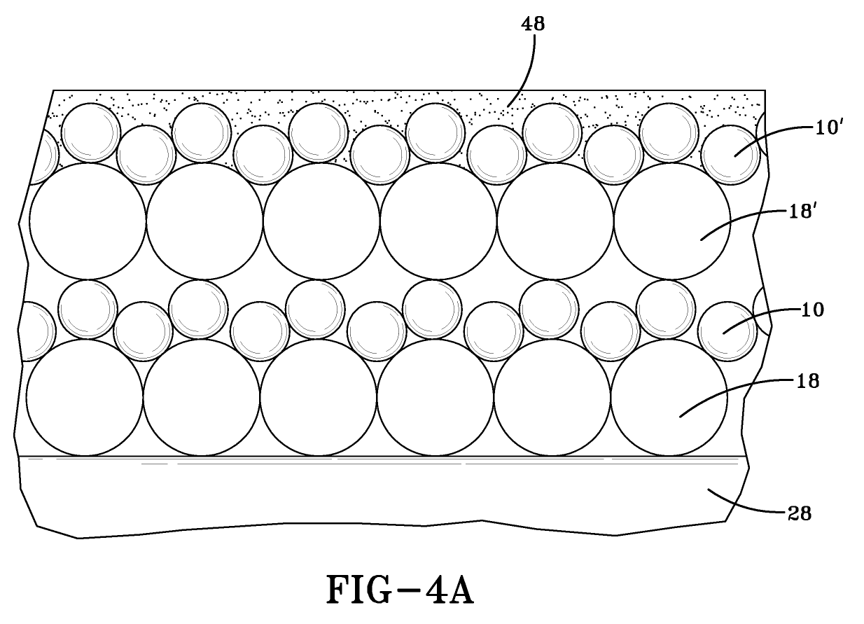

FIG. 4 illustrates a multi-layer arrangement with two layers being illustrated for simplicity. After application of microspheres 10, the fiber 18 is wound around the deposited microspheres 10 to form a second layer 18′ and microspheres 10′ are then deposited on layer 18′.

FIG. 4A illustrates an enlarged portion of the arrangement of FIG. 4. The first layer of fiber 18 is wound around cylinder 28 and a first coating of microspheres 10 is applied. Next, the fiber is wound back on the deposited microspheres 10 to form the second layer of fiber 18′ to which is applied microspheres 10′. A protective coating 48, such as epoxy, may then be applied to the outside of microspheres 10′. Microspheres 10′ may have the same dopant as microspheres 10 or the dopant may be different, in which case two different laser lines of interest will be produced. Thus, a multispectral output may be achieved from a single device, eliminating the need for multiple lasers. Although only two fiber layers are illustrated, an actual unit may have thousands of layers, with a plurality of differently doped microspheres.

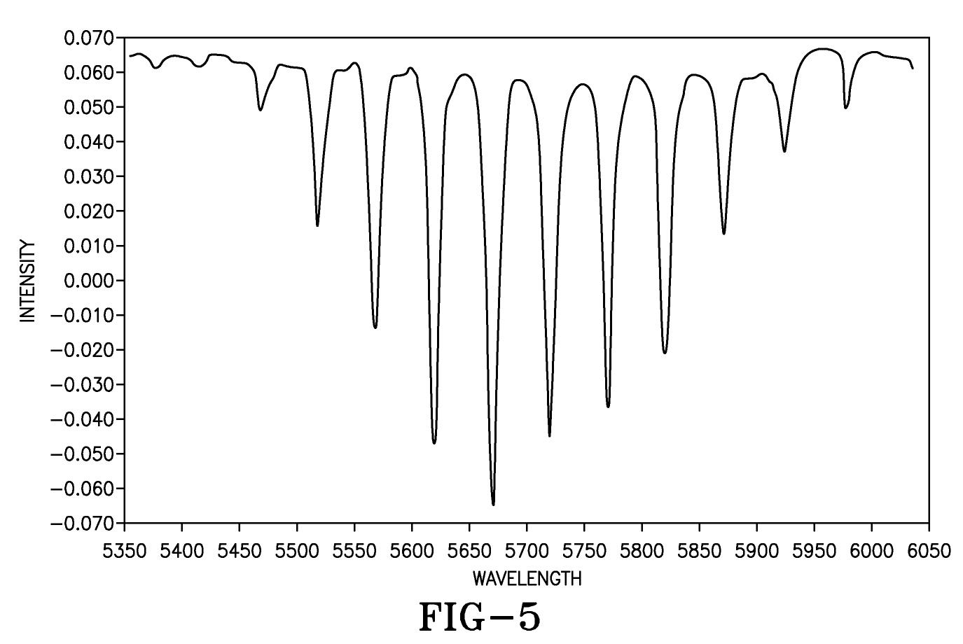

Due to the chemical nature of the dopant used, when a microsphere is pumped with laser energy, the microsphere produces a plurality of output laser lines. For example, FIG. 5 illustrates the output from 5 μm microspheres doped with Rhodamine 6G and pumped with a 532 nm source from a Nd:YAG laser. FIG. 5 shows that for the 5 μm microspheres a plurality of laser output wavelengths from around 5490 Å (Angstroms) to around 5980 Å are produced Although all of the wavelengths may be used for certain applications, in general, only one specific wavelength associated with each specifically doped microsphere is used. The unwanted wavelengths may be filtered out by means of a Fabre-Perot etalon.

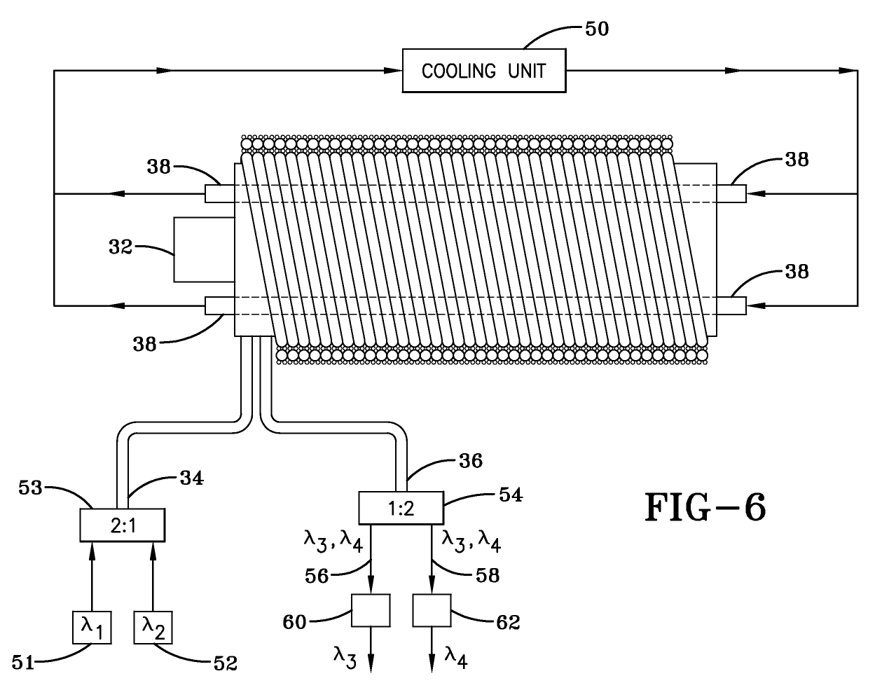

FIG. 6 illustrates the apparatus after application of the microspheres and ready for field use. When the fiber is pumped with the proper pumping source of a particular wavelength the microspheres absorb the pumping energy and lase at different wavelengths. The absorption tends to heat up the system and might contribute to the instability of the system. To prevent overheating, a cooling arrangement is provided to maintain the fiber at a stable temperature. The cooling arrangement includes a cooling unit 50 operable to pump a cooling fluid into the cooling passageways 38 to maintain a desired stable temperature.

The apparatus of FIG. 6 includes two fiber layers and two differently doped microspheres, as in FIG. 4. Two pump laser sources 51 and 52 of two different respective wavelengths λ₁ and λ₂ pump the fiber at the input 34. A 2:1 combiner 53 combines pumping wavelengths λ₁ and λ₂ for launching into the fiber. In response to wavelengths λ₁ and λ₂, the microspheres produce respective wavelengths including wavelengths of interest λ₃ and λ₄ that appear at output end 36. A 1:2 splitter 54 separates the λ₃ and λ₄ wavelengths into two paths 56 and 58. Two different desired individual wavelengths λ₃ and λ₄ may then be obtained with the use of respective etalons 60 and 62. If n different wavelengths are desired with the use of n different dopants, an n:1 combiner may be used at the input 34 and a 1:n splitter may be used at the output 36.

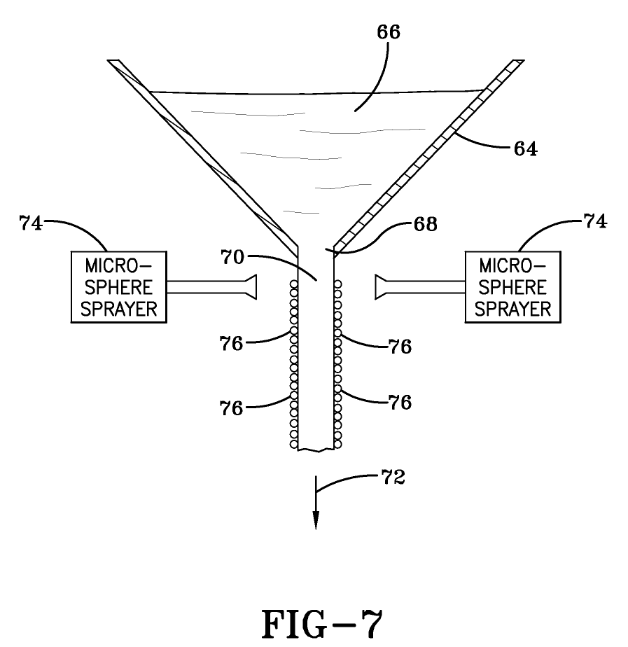

FIG. 7 illustrates an alternative method of adhering the microspheres to an optical fiber. The arrangement of FIG. 7 includes a heated container 64 of a conical shape that holds melted silica 66 (or other material which will form the fiber). The melted silica 66 emerges from an exit 68 at the bottom of the container 64 and starts to solidify into fiber 70 as it is pulled in the direction of arrow 72. At least one, and preferably two microsphere sprayers 74 are positioned near exit 68 and are operable to spray microspheres 76 onto the hot tacky fiber 70. During the pulling process microspheres with other dopants may also be applied. The fiber with microspheres is then wound around a cylinder such as in FIG. 6 for use in the field.

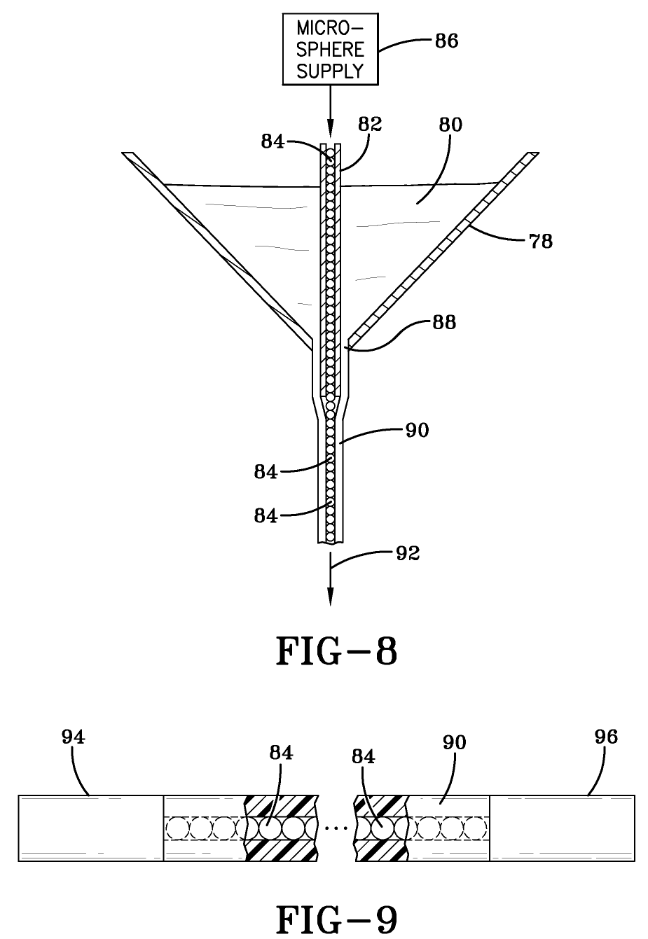

In the embodiment thus far described, the microspheres are adhesively attached to the external surface of the fiber. FIG. 8 illustrates an embodiment wherein the microspheres are internal to a hollow fiber. The arrangement of FIG. 8, in a manner similar to FIG. 7, includes a heated container 78 filled with melted silica 80. Centrally located in the container 78 is a pipe 82 filled with microspheres 84 from a supply 86. Pipe 82 acts as a mandrel such that at exit 88 a hollow fiber 90 is formed and pulled in the direction of arrow 92. As fiber 90 is pulled, its diameter reduces and microspheres 84 adhere to the hot tacky interior of the fiber 90. During the process other microspheres with different dopants may be introduced.

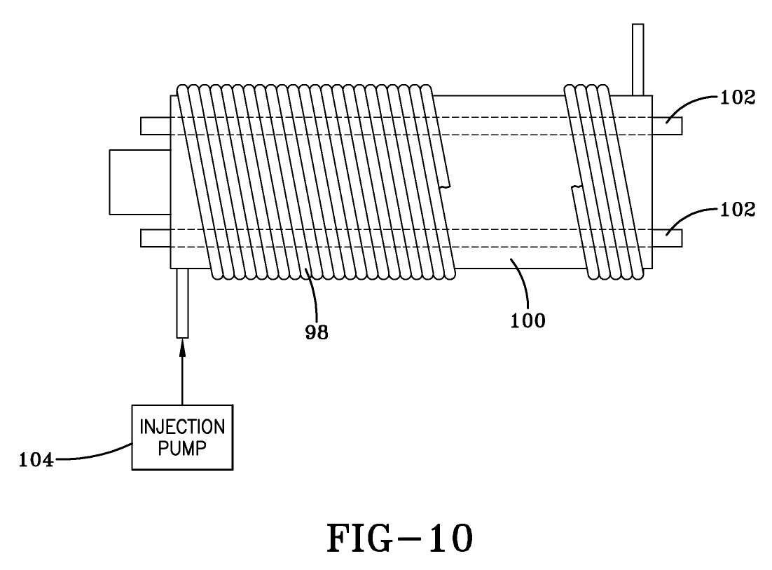

After the desired length of fiber is obtained, and as illustrated in FIG. 9, solid fiber ends 94 and 96 may be affixed or coupled to the respective ends of hollow fiber 90 to facilitate coupling with a combiner and splitter at the respective ends, as in FIG. 6. During fabrication, the hollow fiber 90 is wound around a cylinder, also illustrated in FIG. 6.

FIG. 10 illustrates an alternate method of fabricating a hollow fiber filled with microspheres. In FIG. 10 a hollow fiber 98 is wound around cylinder 100 having internal cooling passageways 102. An injection pump 104 is filled with a fluid, such as water, together with microspheres and is operable to pump the microspheres into the hollow fiber 98. For multiple desired laser wavelengths, all of the different microspheres needed to obtain those desired laser wavelengths may be mixed in the injection pump 104, or they may be added sequentially. After the hollow fiber 98 is filled, solid fiber ends are applied, as in FIG. 9, for coupling energy into and out of the hollow fiber 98.

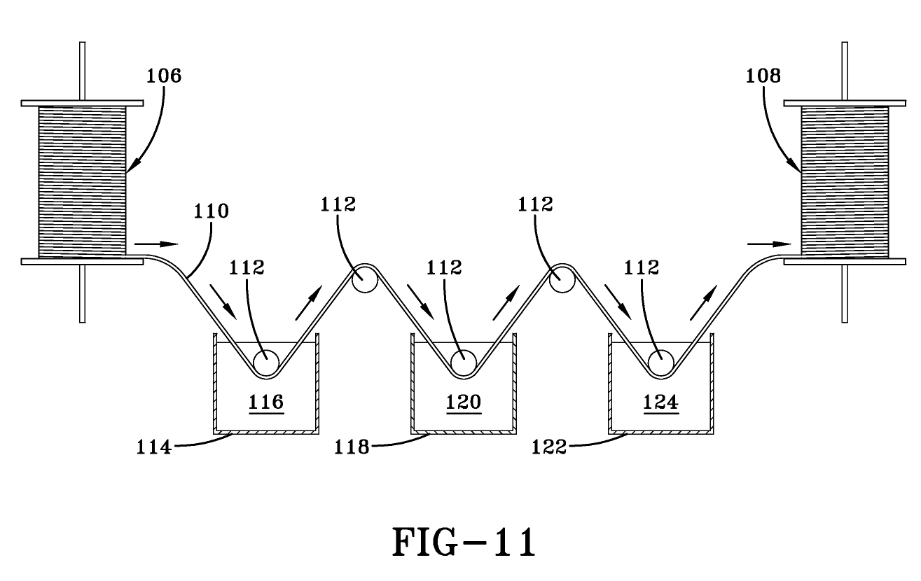

FIG. 11 illustrates another method for adhering the microspheres to a fiber. The arrangement of FIG. 11 includes a supply spool or cylinder 106 and a take-up cylinder 108. A fiber 110 extends from the supply 106 to the take-up cylinder 108 over a series of rollers 112. From the supply cylinder 106 the fiber 110 passes into a container 114 having a solvent 116 for removing the wax coating on the fiber 110. The next container 118 contains an adhesive, such as an epoxy 120, having a similar refractive index as that of the fiber 110. Finally, the fiber 110 passes into container 122 that contains the microspheres 124 of a predetermined dopant. The microspheres 124 adhere to the epoxy coated fiber 110 which is then wound around the take-up cylinder 108. After coating a desired length of fiber 110 with microspheres, the microspheres 124 in container 122 may be replaced with microspheres having a different dopant to coat a subsequent section of fiber. The process may be repeated for as many differently doped microspheres as required.

The microsphere fiber laser system of the invention is cavity free and capable of emitting multiple laser lines for simultaneous multiple task operations. The system is not only compact, but it is rugged, inexpensive, lightweight and durable.

While the invention has been described with reference to certain preferred embodiments, numerous changes, alterations and modifications to the described embodiments are possible without departing from the spirit and scope of the invention as defined in the appended claims, and equivalents thereof.

What is claimed is:

1. A microsphere fiber laser system, comprising:
a laser beam conducting fiber having an input end and an output end;
a plurality of doped microspheres adhesively attached to the fiber; and
at least one pump laser for injecting a laser beam into the input end of the fiber;
wherein the laser beam excites the doped microspheres to generate an output laser beam that is extracted at the output end of the fiber.

2. The system of claim 1 wherein the output laser beam includes a plurality of different wavelengths, the system further comprising at least one etalon at the output end of the fiber for selecting one of the plurality of different wavelengths.

3. The system of claim 1 further comprising a cylinder wherein the fiber is wound around the cylinder.

4. The system of claim 3 wherein the cylinder is a metal cylinder.

5. The system of claim 4 wherein the metal is aluminum.

6. The system of claim 3 wherein the cylinder includes cooling passageways therethrough.

7. The system of claim 1 wherein the fiber and the microspheres are made of the same material.

8. The system of claim 7 wherein the material is silica or polymethylemethacrylate.

9. The system of claim 1 wherein the microspheres are on an external surface of the fiber.

10. The system of claim 1 wherein the fiber is a hollow fiber and the microspheres are on an internal surface of the hollow fiber.

11. The system of claim 1 wherein the doped microspheres include microspheres having different dopants.

12. The system of claim 1 wherein a number of pump lasers is n, the system further comprising an n:1 combiner connected to the n pump lasers for coupling outputs of the n pump lasers to the input end of the fiber.

13. The system of claim 12 further comprising a 1:n splitter coupled to the output end of the fiber for providing n separate laser outputs.

14. A method of making a microsphere laser apparatus, comprising:
winding a laser beam conducting fiber around a rotatable cylinder;
heating the fiber as the cylinder rotates; and
attaching microspheres to the heated fiber as the cylinder rotates.

15. The method of claim 14 further comprising winding the fiber over the attached microspheres and repeating the heating and attaching steps.

16. The method of claim 14 further comprising providing microspheres with different dopants.

17. A method of making a microsphere laser apparatus, comprising:
providing a melt of a laser beam conducting fiber in a container having an opening at a bottom thereof;
drawing the melt out of the container at the opening to solidify the fiber; and
attaching microspheres to the fiber as it is pulled from the container.

18. A method of making a microsphere laser system, comprising:
providing a melt of a laser beam conducting fiber in a container having an opening at a bottom thereof and having a central hollow mandrel;
providing the hollow mandrel with microspheres;
drawing the melt out of the container at the opening to form a hollow fiber; and
inserting the microspheres into the hollow fiber.

19. The method of claim 18 wherein the hollow fiber includes an input end and an output end, the method further comprising connecting solid fibers to the input and output ends of the hollow fiber.

20. A method of making a microsphere laser system, comprising:
winding a hollow fiber around a cylinder; and
injecting microspheres into one end of the hollow fiber.

21. The method of claim 20 further comprising mixing the microspheres with a liquid prior to injecting.

22. A method of making a microsphere laser system, comprising:
providing a fiber, a fiber supply cylinder and a fiber take-up cylinder;
passing the fiber through a solvent to remove a coating on the fiber;
passing the fiber through an adhesive;
passing the fiber through a supply of microspheres; and
winding the fiber around the take-up cylinder.

23. An apparatus, comprising:
a laser beam conducting fiber having an input end and an output end; and
a plurality of doped microspheres disposed inside the fiber.
